(19) United States
(12) Patent Application Publication
(10) Pub. No.: US 2026/0342322 A1
(43) Pub. Date: Oct. 29, 2026

(54) CONTROL METHOD AND APPARATUS FOR OUTPUT PHASE OF BROADBAND SYNCHRONOUS SIGNAL SOURCE AND STORAGE MEDIUM

(71) Applicant: ELECTRIC POWER RESEARCH INSTITUTE, CHINA SOUTHERN POWER GRID, Guangzhou, Guangdong (CN)

(72) Inventors: Wei WU, Guangzhou, Guangdong (CN); Baorong ZHOU, Guangzhou, Guangdong (CN); Chao HONG, Guangzhou, Guangdong (CN); Jin LI, Guangzhou, Guangdong (CN); Yong MEI, Guangzhou, Guangdong (CN); Yuanwei YANG, Guangzhou, Guangdong (CN); Huafeng ZHOU, Guangzhou, Guangdong (CN); Yuming LIU, Guangzhou, Guangdong (CN); Aoyu LEI, Guangzhou, Guangdong (CN)

(73) Assignee: ELECTRIC POWER RESEARCH INSTITUTE, CHINA SOUTHERN POWER GRID, Guangzhou, Guangdong (CN)

(21) Appl. No.: 18/995,538

(22) PCT Filed: Mar. 13, 2024
(86) PCT No.: PCT/CN2024/081354

§ 371 Date: Jan. 16, 2025

(30) Foreign Application Priority Data
Nov. 6, 2023 (CN) 202311460419.0

(51) Int. Cl. H03K 5/135

(52) U.S. Cl. CPC H03K 5/135

(57) ABSTRACT

A method, a device and a storage medium for controlling an output phase of a wide-band synchronous signal source is provided. The method includes: obtaining first and second synchronous sampling sequences respectively based on a pulse-per-second signal and a standard wide-band test signal; determining a sampling time of any rising edge signal in the first synchronous sampling sequence as a first time; determining a corresponding second time in the second synchronous sampling sequence based on a reference value of the standard wide-band test signal and the first time; calculating a phase correction control value based on the first and second time; when a number of phase correction control values is less than a preset threshold, repeating the above steps; when the number of the phase correction control values is greater than the preset threshold, obtaining a final phase correction control value based on phase correction control values

### CROSS-REFERENCE TO RELATED APPLICATIONS

The present application claims priority to Chinese Patent Application No. 202311460419.0, titled “METHOD, DEVICE AND STORAGE MEDIUM FOR CONTROLLING OUTPUT PHASE OF WIDE-BAND SYNCHRONOUS SIGNAL SOURCE”, filed on Nov. 6, 2023 with the China National Intellectual Property Administration, which is incorporated herein by reference in its entirety.

### FIELD

The present disclosure relates to the field of output signal correction, and in particular to a method, a device and a storage medium for controlling an output phase of a wide-band synchronous signal source.

### BACKGROUND

With the construction and development of new-type power systems, power electronics technology is more and more widely used in power grid. All stages of the power system, including power generation, transmission, distribution and consumption, exhibit characteristics of power electronics, accompanied by an increase in nonlinearity. Under the control of a large number of power electronic devices with diverse characteristics, wide-band oscillation occurs in the system, covering a frequency band from near the traditional power frequency 50 Hz to a high frequency band above 1000 Hz. At present, it is difficult to monitor the wide-band oscillation occurring in the power grid. Both domestically and internationally, wide-band oscillation leads to incidents such as off-grid of new energy units, equipment damage, and DC outage from time to time, posing a huge challenge to the safe and stable operation of the system.

To solve the wide-band oscillation, it is first necessary to monitor the wide-band oscillation, so wide-band measurement technology and products have become the focus of research. For a long time, power grid measurement has primarily focused on the traditional power frequency 50 Hz, resulting in existing testing and development platforms being unable to meet the demand of wide-band measurement technology and products development. The core problem is the lack of a wide-band synchronous signal source with high-accuracy phase output. However, existing wide-band synchronous signal sources have low phase output accuracy, making it difficult to meet application requirements.

### SUMMARY

In view of the above, the present disclosure provides a method, a device and a storage medium for controlling an output phase of a wide-band synchronous signal source in which a phase correction control value is obtained based on a pulse-per-second signal and a standard wide-band test signal to correct the output phase of the wide-band synchronous signal source. With the above solution of the present disclosure, the accuracy of the output phase can be improved on the basis of the existing wide-band synchronous signal source.

In a first aspect, the present disclosure provides a method for controlling an output phase of a wide-band synchronous signal source, including:
step S101, setting a master clock signal source to output a pulse-per-second signal;
step S102, setting a parameter of the wide-band synchronous signal source to output a standard wide-band test signal;
step S103, acquiring a first synchronous sampling sequence and a second synchronous sampling sequence respectively based on the pulse-per-second signal and the standard wide-band test signal;
step S104, determining a sampling time of to any rising edge signal in the first synchronous sampling sequence as a first time;
step S105, determining a reference value of the standard wide-band test signal, and determining a corresponding second time in the second synchronous sampling sequence based on the reference value and the first time;
step S106, calculating a phase correction control value based on the first time and the second time, and outputting the phase correction control value;
step S107, when a number of obtained phase correction control values is less than a preset threshold, repeating the steps S102-S106 until the number of obtained phase correction control values is greater than the preset threshold; and
step S108, when the number of obtained phase correction control values is greater than the preset threshold, obtaining a final phase correction control value based on multiple phase correction control values, and obtaining a corrected standard wide-band test signal based on the final phase correction control value.

In an embodiment, the pulse-per-second signal is a one pulse-per-second signal.

In an embodiment, the setting the parameter of the wide-band synchronous signal source to output the standard wide-band test signal includes:

setting a signal amplitude, a signal frequency and a signal phase of the wide-band synchronous signal source to output a standard triangle wave signal as the standard wide-band test signal.

The standard wide-band test signal is expressed by:

Mₙ=f(Aₙ,fₙ,αₙ,t),
where Mₙ indicates the standard wide-band test signal, Aₙ indicates a signal amplitude with a range of Aₙ∈[0,100], fₙ indicates a signal frequency with a range of fₙ∈[0,2500], αₙ indicates a signal phase with a range of αₙ∈[0°,360°], n indicates an n-th phase correction control value.

In an embodiment, the acquiring the first synchronous sampling sequence and the second synchronous sampling sequence respectively based on the pulse-per-second signal and the standard wide-band test signal includes:
setting a start time, an end time and a sampling frequency for a sampling of the pulse-per-second signal and the standard wide-band test signal to be the same;
sampling the pulse-per-second signal and the standard wide-band test signal respectively based on the start time, the end time and the sampling frequency to acquire the first synchronous sampling sequence and the second synchronous sampling sequence.

In an embodiment, the determining the reference value of the standard wide-band test signal and the determining the corresponding second time in the second synchronous sampling sequence based on the reference value and the first time includes:
selecting a standard wide-band test signal value of the standard wide-band test signal at the start time as the reference value;
determining sampling signal values that meet a preset condition in the second synchronous sampling sequence based on to the reference value;
calculating a difference between a sampling time of each of the sampling signal values and the first time, and selecting a sampling time with a smallest difference from the first time as the second time.

In a second aspect, the present disclosure further provides a device for controlling an output phase of a wide-band synchronous signal source, including:
a first signal output module configured to set a master clock signal source to output a pulse-per-second signal;
a second signal output module configured to set a parameter of the wide-band synchronous signal source to output a standard wide-band test signal;
a synchronous sampling module configured to acquire a first synchronous sampling sequence and a second synchronous sampling sequence respectively based on the pulse-per-second signal and the standard wide-band test signal;
a first time determination module configured to determine a sampling time of any rising edge signal in the first synchronous sampling sequence as a first time;
a second time determination module configured to determine a reference value of the standard wide-band test signal, and determine a corresponding second time in the second synchronous sampling sequence based on the reference value and the first time;
a phase correction calculation module configured to calculate a phase correction control value based on the first time and the second time, and output the phase correction control value;
a phase correction recalculation module configured to, when a number of obtained phase correction control values is less than a preset threshold, repeat the processes of the second signal output module, the synchronous sampling module, the first time determination module, the second time determination module and the phase correction calculation module until the number of obtained phase correction control values is greater than the preset threshold; and
a final phase correction determination module configured to, when the number of the obtained phase correction control values is greater than the preset threshold, obtain a final phase correction control value based on multiple phase correction control values, and obtain a corrected standard wide-band test signal based on the final phase correction control value.

In a third aspect, the present disclosure further provides a computer-readable storage medium having a computer program stored thereon, the computer program, when executed by a processor, implements the steps of any of the method for controlling the output phase of the wide-band synchronous signal source according to the first aspect.

In a fourth aspect, the present disclosure further provides a computer device, including a memory and a processor, wherein the memory stores a computer program, and the processor implements, when executing the computer program, any of the method for controlling the output phase of the wide-band synchronous signal source according to the first aspect.

According to an embodiment of the present disclosure, a first synchronous sampling sequence and a second synchronous sampling sequence are acquired by sampling a pulse-per-second signal and a standard wide-band test signal synchronously. Based on the first synchronous sampling sequence and the second synchronous sampling sequence, multiple phase correction control values are obtained to be used for calculating a final phase correction control value by taking their average, and then the final phase correction control value is used to correct the standard wide-band test signal to obtain the corrected standard wide-band test signal. With the above solution of the present disclosure, high-accuracy phase output is achieved based entirely on hardware structure of the existing wide-band synchronous signal source, thereby meeting the application requirements for wide-band detection in new-type power systems.

### BRIEF DESCRIPTION OF THE DRAWINGS

For more clearly illustrating the technical solutions in the embodiments of the present disclosure or the related art, drawings for describing the embodiments or the related art will be briefly described hereinafter.

FIG. 1 is a schematic diagram of a method for controlling an output phase of a wide-band synchronous signal source in an embodiment of the present disclosure;

FIG. 2 is a schematic flowchart of a method for controlling an output phase of a wide-band synchronous signal source in an embodiment of the present disclosure;

FIG. 3 is a schematic diagram of a system for controlling an output phase of a wide-band synchronous signal source in an embodiment of the present disclosure;

FIG. 4 is a schematic diagram of preset conditions for extracting sampling signal values from a second synchronous sampling sequence in an embodiment of the present disclosure;

FIG. 5 is a schematic diagram of a first synchronous sampling sequence and a second synchronous sampling sequence when obtaining a first phase correction control value in an embodiment of the present disclosure;

FIG. 6 is a schematic diagram of a first synchronous sampling sequence and a second synchronous sampling sequence when obtaining a second phase correction control value in an embodiment of the present disclosure; and

FIG. 7 is a schematic diagram of a device for controlling an output phase of a wide-band synchronous signal source in an embodiment of the present disclosure.

### DETAILED DESCRIPTION OF THE EMBODIMENTS

Hereinafter, the embodiments of the present disclosure will be described clearly and completely in conjunction with the accompanying drawings in the embodiments of the present disclosure. It is apparent that the described embodiments are only some embodiments of the present disclosure, rather than all embodiments. Based on the embodiments of the present disclosure, all other embodiments obtained by those skilled in the art without any creative effort fall within the protection scope of the present disclosure. In order to explain the present disclosure in more detail, a method, a device and a storage medium for controlling an output phase of a wide-band synchronous signal source according to the present disclosure are specifically described below in conjunction with the accompanying drawings.

With the construction and development of new-type power systems, power electronics technology is more and more widely used in power grid. All stages of the power system, including power generation, transmission, distribution and consumption, exhibit characteristics of power electronics, accompanied by an increase in nonlinearity. The phenomenon of wide-band oscillation, with frequencies ranging from 5 Hz to 2500 Hz, represents a novel challenge in the current power system, and poses significant difficulties in practical monitoring. Wide-band measurement technology and products development are crucial in addressing the problem of wide-band oscillation. Among the most central challenges in these efforts is the lack of a wide-band synchronous signal source with high-accuracy phase output.

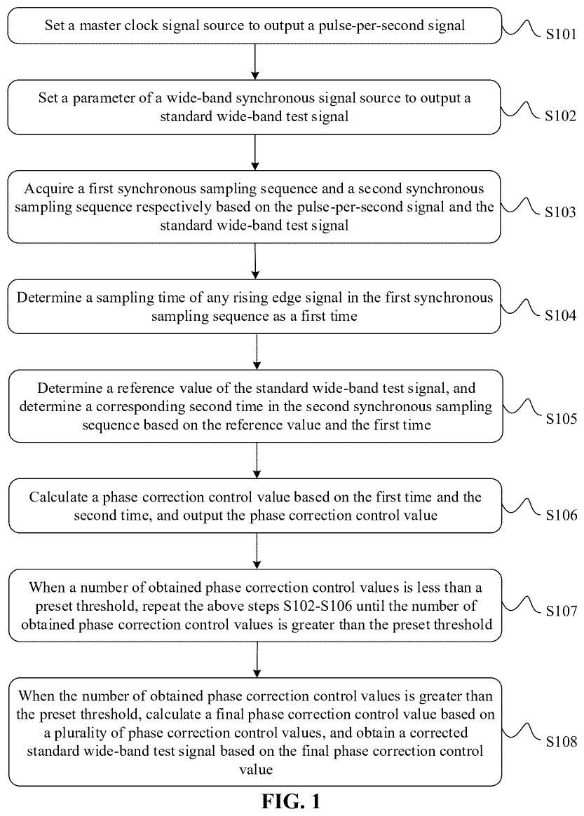

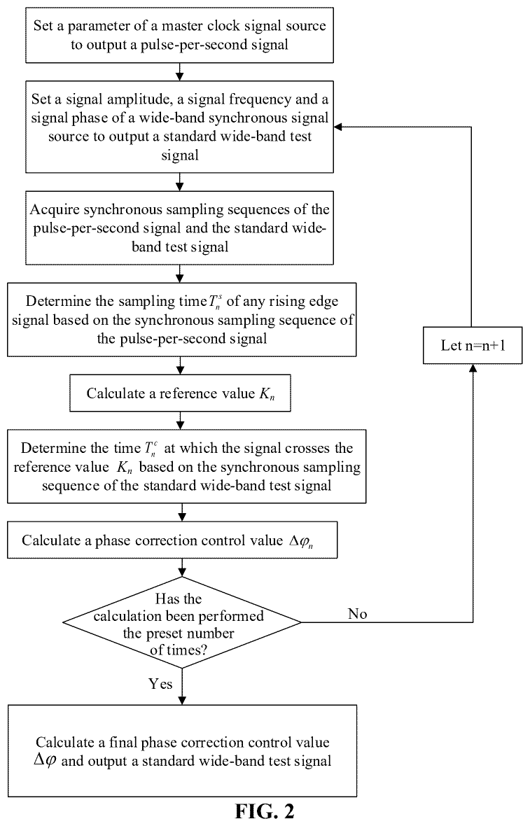

To address this, the present disclosure provides a method for controlling an output phase of a wide-band synchronous signal source, which enables the output of a wide-band synchronous signal with high-accuracy phase without any changes to the hardware devices. Take the application of this method in terminal devices as an example for illustration, in conjunction with the schematic diagram of the method for controlling the output phase of the wide-band synchronous signal source shown in FIG. 1 and the schematic flowchart of the method for controlling the output phase of the wide-band synchronous signal source shown in FIG. 2.

The method for controlling the output phase of the wide-band synchronous signal source of the present disclosure is further provided with a system for controlling the output phase of the wide-band synchronous signal source. Referring to FIG. 3, the system includes a satellite antenna, a master clock signal source, a wide-band synchronous signal source and a sampling device. The satellite antenna is a SYN108 Beidou/GPS dual-mode timing antenna, which is configured to provide satellite signals to the master clock signal source. The master clock signal source is a SYN2411 IEEE1588 clock, which is configured to receive satellite signals and output a synchronous clock signal and a pulse-per-second signal. The wide-band synchronous signal source is a LDDL-PMU430 three-phase high-frequency harmonic synchronous signal source, which is configured to generate a standard wide-band test signal. The sampling device is a DSO-X3024A digital oscilloscope, which is configured to sample the pulse-per-second signal and the standard wide-band test signal synchronously.

An embodiment of the present disclosure provides an application scenario where the method for controlling the output phase of the wide-band synchronous signal source is applied. The application scenario includes terminal devices provided in the embodiment. The terminal devices include but are not limited to smart phones and computer devices. The computer devices may be at least one of desktop computers, portable computers, laptop computers, mainframe computers, tablet computers and the like. The user operates the terminal device to obtain a corrected standard wide-band test signal. The specific process may refer to an embodiment of a method for controlling an output phase of a wide-band synchronous signal source.

The method for controlling the output phase of the wide-band synchronous signal source according to an embodiment of the present disclosure includes steps S101-S108.

In step S101, a master clock signal source is set to output a pulse-per-second signal.

In an embodiment, the pulse-per-second signal is a one pulse-per-second signal. The master clock signal source in the embodiment provides a synchronous clock signal to the wide-band synchronous signal source, thus simplifying the system as well as the connection within the system.

In step S102, a parameter of the wide-band synchronous signal source is set to output a standard wide-band test signal.

The parameter of the wide-band synchronous signal source includes a signal amplitude, a signal frequency and a signal phase. By setting the signal amplitude, the signal frequency and the signal phase of the wide-band synchronous signal source, a standard triangle wave signal is output as the standard wide-band test signal, which is expressed by:

Mₙ=f(Aₙ,fₙ,αₙ,t),
where Mₙ indicates the standard wide-band test signal, Aₙ indicates the signal amplitude with a range of Aₙ∈[0,100], fₙ indicates the signal frequency with a range of fₙ∈[0,2500], αₙ indicates the signal phase with a range of αₙ∈[0°,360°], t indicates the time, and n indicates an n-th phase correction control value.

In step S103, a first synchronous sampling sequence and a second synchronous sampling sequence are acquired respectively based on the pulse-per-second signal and the standard wide-band test signal.

A start time, an end time and a sampling frequency for a sampling of the pulse-per-second signal and the standard wide-band test signal are set to be the same;

The first synchronous sampling sequence and the second synchronous sampling sequence are acquired by sampling the pulse-per-second signal and the standard wide-band signal based on the start time, the end time and the sampling frequency. The first synchronous sampling sequence is denoted as

$$\{ ( {t}_{n}^{1} , {Y}_{n}^{1} ) , ( {t}_{n}^{2} , {Y}_{n}^{2} ) , … , ( {t}_{n}^{c} , {Y}_{n}^{c} ) \} ,$$

and the second synchronous sampling sequence is denoted as

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

where c is the total number of samples in the sampling sequence, n indicates that the synchronous sampling sequence is acquired during the process of obtaining the n-th phase correction control value, n is a constant greater than 0,

$${t}_{n}^{c}$$

is the sampling time,

$${Y}_{n}^{c}$$

is the sampling signal value of the pulse-per-second signal at the time

$${t}_{n}^{c} , and {M}_{n}^{c}$$

is the signal value of the standard wide-band test signal at the time

$${t}_{n}^{c} .$$

In step S104, a sampling time of any rising edge signal in the first synchronous sampling sequence is determined as a first time.

In the first synchronous sampling sequence

$$\{ ( {t}_{n}^{1} , {Y}_{n}^{1} ) , ( {t}_{n}^{2} , {Y}_{n}^{2} ) , … , ( {t}_{n}^{c} , {Y}_{n}^{c} ) \} ,$$

a rising edge signal

$${Y}_{n}^{i}$$

is arbitrarily determined, and the sampling time

$${t}_{n}^{i}$$

of the rising edge signal

$${Y}_{n}^{i}$$

is determined as the first time

$${T}_{n}^{s} .$$

The condition for determining the rising edge signal

$${Y}_{n}^{i}$$

is:

$${Y}_{n}^{i} \leq 0 \leq {Y}_{n}^{i + 1} .$$

In step S105, a reference value of the standard wide-band test signal is determined, and a corresponding second time in the second synchronous sampling sequence is determined based on the reference value and the first time.

In an embodiment, step S105 includes steps S201-S203.

In step S201, a standard wide-band test signal value of the standard wide-band test signal Mₙ=f(Aₙ,fₙ,αₙ,t) at the starting time, i.e., t=0, is selected as a reference value, which denoted as Kₙ=f(Aₙ,fₙ,αₙ,0), Kₙ is the reference value.

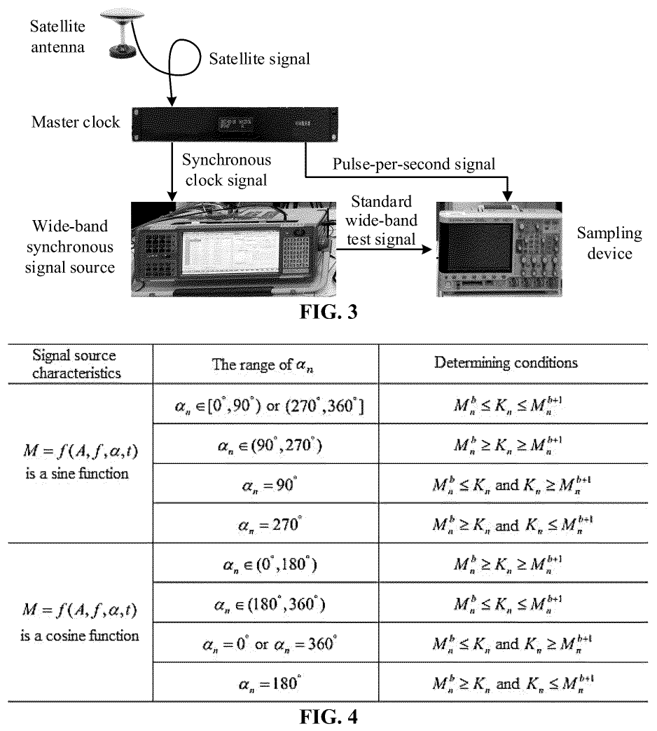

In step S202, sampling signal values that meet a preset condition in the second synchronous sampling sequence is determined based on the reference value Kₙ, wherein the preset condition may be referred to in FIG. 4, and the sequence of sampling signal values that meet the preset condition may be denoted as

$$\{ ( {t}_{n}^{b 1} , {M}_{n}^{b 1} ) , ( {t}_{n}^{b 2} , {M}_{n}^{b 2} ) , … , ( {t}_{n}^{bj} , {M}_{n}^{bj} ) \} ,$$

where bⱼ≤c.

In step S203, a difference between the sampling time of each of the sampling signal values and the first time is calculated, and a sampling time with a smallest difference from the first time is selected as the second time. The difference between the sampling time of each of the sampling signal values and the first time is expressed by:

$${T}_{n} = \vert {T}_{n}^{s} - {t}_{n}^{k} \vert , k = \{ b 1 , b 2 , … , bj \} ,$$

where Tₙ is the difference between the sampling time of the sampling signal value and the first time, and

$${t}_{n}^{k}$$

is the sampling time of the sampling signal value.

In step S106, a phase correction control value is calculated based on the first time and the second time, and the phase correction control value is output.

The phase correction control value is expressed by:

$${Δφ}_{n} = 360 \times {f}_{n} \times ( {T}_{n}^{c} - {T}_{n}^{s} ) ,$$

where Δφₙ indicates an n-th phase correction control value, fₙ indicates the signal frequency of the standard wide-band test signal,

$${T}_{n}^{s}$$

indicates the first time, and

$${T}_{n}^{c}$$

indicates the second time.

In step S107, when a number of obtained phase correction control values is less than a preset threshold, the above steps S102-S106 are repeated until the number of obtained phase correction control values is greater than the preset threshold.

The preset threshold is a constant greater than 1, preferably ranging from 3 to 5, which can be determined based on the phase correction accuracy of the standard wide-band test signal. By repeatedly obtaining the phase correction control value through step S107, a final phase correction control value with higher accuracy may be calculated based on multiple phase correction control values, thereby achieving the correction of the standard wide-band test signal.

Step S108, when the number of obtained phase correction control values is greater than the preset threshold, a final phase correction control value is obtained based on multiple the phase correction control values, and a corrected standard wide-band test signal is obtained based on the final phase correction control value.

The final phase correction control value is expressed by:

$$Δφ = \frac{1}{H} ( {Δφ}_{1} + {Δφ}_{2} + … + {Δφ}_{H} ) ,$$

where Δφ indicates the final phase correction control value, H indicates the preset threshold, and Δφ_{H} indicates an H-th phase correction control value.

Through the above-mentioned method for controlling the output phase of the wide-band synchronous signal source, the pulse-per-second signal and the standard wide-band test signal are sampled synchronously. The sampling time of any rising edge is determined in the synchronous sampling sequence of the pulse-per-second signal. The reference value is calculated based on the initial parameters of the wide-band synchronous signal source. The correction control value is then calculated to correct the output phase of the existing wide-band synchronous signal source, thereby improving the accuracy of the output phase. This method is entirely based on the hardware structure of the existing wide-band synchronous signal source, without any hardware modifications or replacements. By employing the above method, high-accuracy phase output can be achieved, which fully meets the application requirements of wide-band detection in new-type power systems.

In an embodiment, the preset condition in the above step S202 are as follows.

When the standard wide-band test signal Mₙ=f(Aₙ,fₙ,αₙ,t) is a sine function, there are the following four cases:
(1) If α∈[0°, 90°) or α∈(270°,360°], then Mₙ=f(Aₙ,fₙ,αₙ,t) is a monotonically increasing function in this interval. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{bi}$$

(i is an arbitrary constant, 1≤i≤c−1) that meets the following condition

$${M}_{n}^{bi} \leq {K}_{n} \leq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{bj} , {M}_{n}^{bj} ) \} .$$

(2) If α∈(90°, 270°), then Mₙ=f(Aₙ,fₙ,αₙ,t) is a monotonically decreasing function in this interval. In the second synchronous sampling the sampling signal value sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal

$${M}_{n}^{bi}$$

(i is an arbitrary constant, 1≤i≤c−1) that meets the following condition

$${M}_{n}^{bi} \geq {K}_{n} \geq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{bj} , {M}_{n}^{bj} ) \} .$$

(3) If α=90°, then Mₙ=f(Aₙ,fₙ,αₙ,t) takes a maximum value. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{bi}$$

(i is an arbitrary constant, 1≤i≤c−1) that meets the following condition

$${M}_{n}^{bi} \leq {K}_{n} and {K}_{n} \geq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

(4) If α=270°, then Mₙ=f(Aₙ,fₙ,αₙ,t) takes a minimum value. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{bi}$$

(i is an arbitrary constant, 1≤i≤c−1) that meets the following condition

$${M}_{n}^{bi} \geq {K}_{n} and {K}_{n} \leq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

Similarly, when the standard wide-band test signal Mₙ=f(Aₙ,fₙ,αₙ,t) is a cosine function, there are the following four cases:
(1) If α∈(0°, 180°), then Mₙ=f(Aₙ,fₙ,αₙ,t) is a monotonically decreasing function in this interval. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{bi}$$

(i is an arbitrary constant, 1≤i≤c−1) that meets the following condition

$${M}_{n}^{bi} \geq {K}_{n} \geq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

(2) If α∈(180°,360°), then Mₙ=f(Aₙ,fₙ,αₙ,t) is a monotonically increasing function in this interval. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{bi}$$

(i is an arbitrary constant, 1≤i≤c−1) that meets the following condition

$${M}_{n}^{bi} \leq {K}_{n} \leq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

(3) If α=0° or α=360°, then Mₙ=f(Aₙ,fₙ,αₙ,t) takes a maximum value. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{b i}$$

(i is an arbitrary constant, 1≤i≤c−1) that meets the following condition

$${M}_{n}^{bi} \leq {K}_{n} and {K}_{n} \geq {M}_{n}^{bi + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

(4) If α=180°, then Mₙ=f(Aₙ,fₙ,αₙ,t) takes a minimum value. In the second synchronous sampling sequence

$$\{ ( {t}_{n}^{1} , {M}_{n}^{1} ) , ( {t}_{n}^{2} , {M}_{n}^{2} ) , … , ( {t}_{n}^{c} , {M}_{n}^{c} ) \} ,$$

the sampling signal value

$${M}_{n}^{b i}$$

(i is an arbitrary constant, 1≤i≤c−1) that meets the following condition

$${M}_{n}^{b i} \geq {K}_{n} and {K}_{n} \leq {M}_{n}^{b i + 1}$$

is selected. The sampling signal values that meet the preset condition in the second synchronous sampling sequence constitute a set of the sampling signal values

$$\{ ( {t}_{n}^{b 1} , {M}_{n}^{b 1} ) , ( {t}_{n}^{b 2} , {M}_{n}^{b 2} ) , … , ( {t}_{n}^{b j} , {M}_{n}^{b j} ) \} .$$

In order to better illustrate the method for controlling the output phase of the wide-band synchronous signal source according to the present disclosure, specific examples are introduced for illustration. In an embodiment, the method includes steps S301-S308.

In step S301, a master clock signal source is set to output a one pulse-per-second signal.

In step S302, a wide-band synchronous signal source is set to output a sine wave signal with the signal amplitude of 10V, the signal frequency of 1000 Hz and the signal phase of 270°. That is, the output standard wide-band test signal is expressed by: M₁=f(A₁,f₁,α₁,t)=10×cos(2π×1000×t+270°).

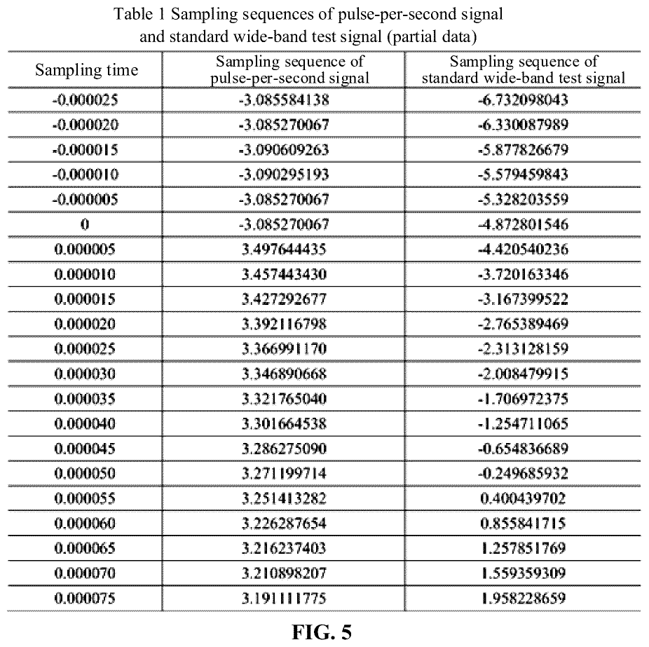

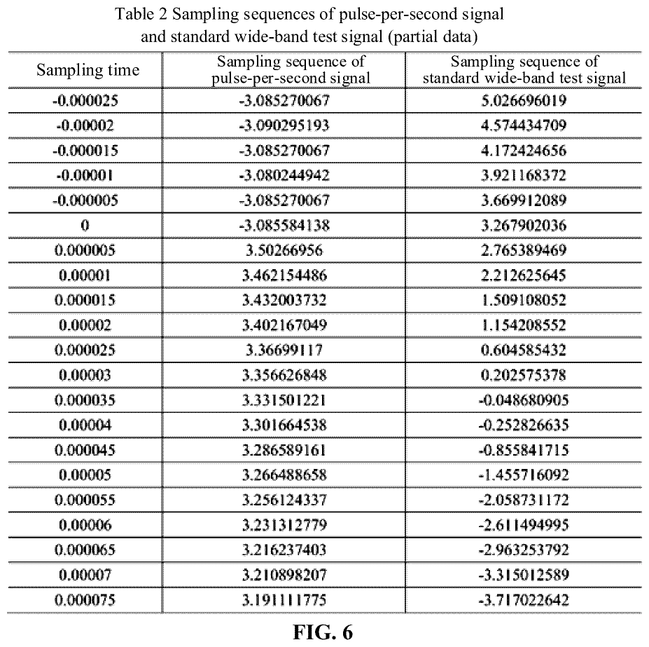

In step S303, the sampling frequency is set to 200 kHz, i.e., the sampling time interval is 5 μs. The sampling time of the rising edge of the pulse-per-second signal is taken as the time reference of 0, a negative sampling time indicates that it occurs before the time reference, and a positive sampling time indicates it occurs after the time reference. A first synchronous sampling sequence and a second synchronous sampling sequence are obtained respectively by sampling the pulse-per-second signal and the standard wide-band test signal synchronously, in which the total sampling time is 5 ms, and the length of the obtained sampling sequence is 1000 points. Here, reference is made to FIG. 5 which shows partial sampling sequences near the time reference of 0.

In step S304, since

$${Y}_{n}^{i} = - 3.085270067 < 0 < {Y}_{n}^{i + 1} = 3.497644435 ,$$

the sampling time of the signal with the sampling signal value

$${Y}_{n}^{i} = - 3.085270067$$

is set to 0, i.e.,

$${T}_{1}^{s} = 0 .$$

In step S305, since the standard wide-band test signal is a cosine function and α=270°∈(180°,360°), the sampling signal values that meet

$${M}_{n}^{b i} \leq {K}_{n} \leq {M}_{n}^{b i + 1}$$

are selected as a sequence of the sampling signal values as follow:

$$\{ \begin{matrix}( - 0.001 \; 95 , - 0.249685932 ) , ( - 0.000 \; 95 , - 0.252826635 ) , \\ ( 0. 00 \; 05 , - 0.249685932 ) , ( 0.00105 , - 0.202575378 ) , \\ ( 0.002 \; 05 , - 0.249685932 )\end{matrix} \}$$

By comparing the difference between the sampling time of each of the above sampling signal values and the first time, it can be found that the difference is the smallest when

$${t}_{n}^{k} = 0.00005 ,$$

and thus the second time is obtained as

$${T}_{1}^{c} = 0.00005 .$$

In step S306, a phase correction control value is calculated by

$${Δφ}_{1} = 360 \times {f}_{1} \times ( {T}_{1}^{c} - {T}_{1}^{s} ) = 360 \times 1000 \times ( 0.00005 - 0 ) = 18 ° .$$

In step S307, if the number of obtained phase correction control values is less than a preset threshold, the above steps S302-S306 are repeated until the number of obtained phase correction control values is greater than the preset threshold.

When obtaining a second phase correction control value, the output standard wide-band test signal is expressed by: M₂=f(A₂,f₂,α₂,t)=57.735×cos(2π×1000×t+90°). A first synchronous sampling sequence and a second synchronous sampling sequence are shown in FIG. 6, and a sequence of the sampling signal values that meet the preset condition in the second synchronous sampling sequence is:

$$\{ \begin{matrix}( - 0.00197 , 0.303077892 ) , ( - 0.000965 , 0.051821608 ) , \\ ( 0. 0003 , 0.2025753 \; 78 ) , ( 0.001035 , 0.001570352 ) , \\ ( 0.002035 , 0.048680905 )\end{matrix} \}$$

Thus the second time is obtained as

$${T}_{2}^{c} = 0.00003 ,$$

and a second phase correction control value is

$$Δ {φ}_{2} = 360 \times {f}_{2} \times ( {T}_{2}^{c} - {T}_{2}^{s} ) = 360 \times 1000 \times ( 0.00003 - 0 ) = 10.8 ° .$$

In step S308, a final phase correction control value is calculated based on the two above-mentioned phase correction control values:

$$Δ φ = \frac{1}{2} ( Δ {φ}_{1} + Δ {φ}_{2} ) = \frac{1}{2} ( 18 ° + 10.8 ° ) = 14.4 ° ,$$

and the standard wide-band test signal is corrected based on the final phase correction control value.

It should be understood that, although the steps illustrated in the flowcharts in FIGS. 1-3 are presented in order as indicated by the arrows, the execution of these steps is not necessarily carried out in this order. Unless otherwise specified herein, there is no strict restriction on the order of execution, and these steps may be performed in various orders. Furthermore, at least a part of the steps illustrated in FIGS. 1-3 may include multiple sub-steps or sub-stages, which are not required to be executed simultaneously but may occur at different times. The execution order of these sub-steps or stages is not necessarily sequential and may be carried out in turn or alternately with other steps, or with the sub-steps of other steps or at least a part of stages.

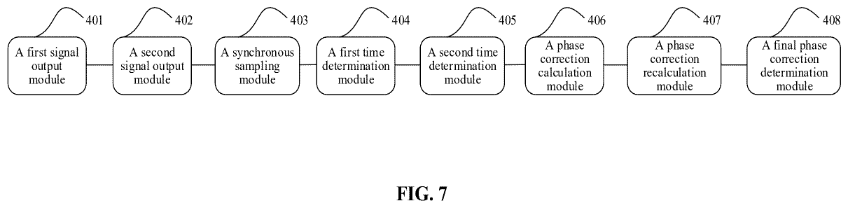

In above-mentioned embodiment of the present disclosure, the method for controlling the output phase of the wide-band synchronous signal source is described in detail. The above-mentioned method in the embodiment of the present disclosure can be implemented by various forms of devices. Therefore, the present disclosure further discloses a device for controlling an output phase of a wide-band synchronous signal source accordingly. A specific embodiment is given below for detailed description in conjunction with FIG. 7.

The device for controlling the output phase of the wide-band synchronous signal source includes a first signal output module 401, a second signal output module 402, a synchronous sampling module 403, a first time determination module 404, a second time determination module 405, a phase correction calculation module 406, a phase correction recalculation module 407 and a final phase correction determination module 408.

The first signal output module 401 is configured to set a master clock signal source to output a pulse-per-second signal.

The second signal output module 402 is configured to set a parameter of the wide-band synchronous signal source to output a standard wide-band test signal.

The synchronous sampling module 403 is configured to acquire a first synchronous sampling sequence and a second synchronous sampling sequence respectively based on the pulse-per-second signal and the standard wide-band test signal.

The first time determination module 404 is configured to determine a sampling time of any rising edge signal in the first synchronous sampling sequence as a first time.

The second time determination module 405 is configured to determine a reference value of the standard wide-band test signal, and determine a corresponding second time in the second synchronous sampling sequence based on the reference value and the first time.

The phase correction calculation module 406 is configured to calculate a phase correction control value based on the first time and the second time, and output the phase correction value.

The phase correction recalculation module 407 is configured to, when a number of obtained phase correction control values is less than a preset threshold, repeat the processes of the second signal output module, the synchronous sampling module, the first time determination module, the second time determination module and the phase correction calculation module until the number of obtained phase correction control values is greater than the preset threshold.

The final phase correction determination module 408 is configured to, when the number of obtained phase correction control values is greater than the preset threshold, obtain a final phase correction control value based on multiple phase correction control values, and obtain a corrected standard wide-band test signal based on the final phase correction control value.

The detailed specifications of the device for controlling the output phase of the wide-band synchronous signal source can be referred to that of the method, and will not be repeated here. Each module in the above device can be implemented in whole or in part by software, hardware and a combination thereof. Each of the above modules can be embedded in or independent of the processor of the terminal device in the form of hardware, or can be stored in the memory of the terminal device in the form of software, so that the processor calls and executes the operations corresponding to each of the above modules.

In an embodiment, the present disclosure further provides a computer-readable storage medium having a computer program stored thereon, the computer program, when executed by a processor, implements the steps of the method for controlling the output phase of the wide-band synchronous signal source.

The computer-readable storage medium may be an electronic memory such as a flash memory, an EEPROM (electrically erasable programmable read-only memory), an EPROM (erasable programmable read-only memory), a hard disk or a ROM (read-only memory). Optionally, the computer-readable storage medium includes a non-transitory computer-readable storage medium. The computer-readable storage medium has a storage space for program codes for executing any method step of the above method. These program codes may be read from or written into one or more computer program products, and the program codes may be compressed in an appropriate form.

In an embodiment, the present disclosure provides a computer device including a memory and a processor, wherein the memory stores a computer program, and the processor implements, when executing the computer program, the method for controlling the output phase of a wide-band synchronous signal source.

The computer device includes the memory, the processor and one or more computer programs, wherein the one or more computer programs can be stored in the memory and configured to be executed by one or more processors, and the one or more application programs are configured to execute the method for controlling the output phase of the wide-band synchronous signal source.

The processor may include one or more processing cores. The processor uses various interfaces and lines to connect the various parts of the computer device, executes various functions of the computer device and processes data by running or executing instructions, programs, code sets or instruction sets stored in the memory, and calling data stored in the memory. Optionally, the processor may be implemented in at least one hardware in form of Digital Signal Processing (DSP), Field-Programmable Gate Array (FPGA), and Programmable Logic Array (PLA). The processor can integrate one or more combinations of a Central Processing Unit (CPU), reporting validator for buried data (Graphics Processing Unit, GPU), and a modem. Among them, the CPU mainly processes operating system, user interface, and application programs; the GPU is configured to render and draw display content; and the modem is configured to process wireless communications. It can be understood that the above-mentioned modem may not be integrated into the processor, but may be implemented separately through a communication chip.

The memory may include a random access memory (RAM) or may include a read-only memory (ROM). The memory is configured to store instructions, programs, codes, code sets or instruction sets, and includes a program storage area and a data storage area. The program storage area may store instructions for implementing operating system, instructions for implementing at least one function (such as a touch function, a sound playback function, an image playback function, etc.), instructions for implementing various embodiments of the above-mentioned method, and the like. The data storage area may also store data created by terminal devices during use, and the like.

In summary, the above embodiments are only for illustrating the technical solutions of the present disclosure, and are not intended to limit the present disclosure. Although the present disclosure is illustrated in detail with reference to the embodiments described above, it should be understood by those skilled in the art that modification can be made to the technical solutions recited in the embodiments described above, or equivalent substitution can be made to a part of technical features of the technical solution. The modifications and equivalent replacements will not make the corresponding technical solutions deviate from the scope of the technical solutions in the embodiments of the present disclosure.

What is claimed is:

1. A method for controlling an output phase of a wide-band synchronous signal source, comprising:
step S101, setting a master clock signal source to output a pulse-per-second signal;
step S102, setting a parameter of the wide-band synchronous signal source to output a standard wide-band test signal;
step S103, acquiring a first synchronous sampling sequence and a second synchronous sampling sequence respectively based on the pulse-per-second signal and the standard wide-band test signal;
step S104, determining a sampling time of any rising edge signal in the first synchronous sampling sequence as a first time;
step S105, determining a reference value of the standard wide-band test signal, and determining a corresponding second time in the second synchronous sampling sequence based on the reference value and the first time;
step S106, calculating a phase correction control value based on the first time and the second time, and outputting the phase correction control value;
step S107, when a number of obtained phase correction control values is less than a preset threshold, repeating the steps S102-S106, until the number of obtained phase correction control values is greater than the preset threshold; and
step S108, when the number of obtained phase correction control values is greater than the preset threshold, obtaining a final phase correction control value based on a plurality of phase correction control values, and obtaining a corrected standard wide-band test signal based on the final phase correction control value.

2. The method for controlling the output phase of the wide-band synchronous signal source according to claim 1, wherein the pulse-per-second signal is a one pulse-per-second signal.

3. The method for controlling the output phase of the wide-band synchronous signal source according to claim 2, wherein the setting the parameter of the wide-band synchronous signal source to output the standard wide-band test signal comprises:
setting a signal amplitude, a signal frequency and a signal phase of the wide-band synchronous signal source to output a standard triangle wave signal as the standard wide-band test signal;
wherein the standard wide-band test signal is expressed by:
Mₙ=f(Aₙ,fₙ,αₙ,t),
where Mₙ indicates the standard wide-band test signal, Aₙ indicates a signal amplitude with a range of Aₙ∈[0,100], fₙ indicates a signal frequency with a range of fₙ∈[0,2500], αₙ indicates a signal phase with a range of αₙ∈[0°,360°], t indicates a time, and n indicates an n-th phase correction control value.

4. The method for controlling the output phase of the wide-band synchronous signal source according to claim 3, wherein the acquiring the first synchronous sampling sequence and the second synchronous sampling sequence respectively based on the pulse-per-second signal and the standard wide-band test signal comprises:
setting a start time, an end time and a sampling frequency for a sampling of the pulse-per-second signal and the standard wide-band test signal to be the same;
sampling the pulse-per-second signal and the standard wide-band test signal respectively based on the start time, the end time and the sampling frequency to acquire the first synchronous sampling sequence and the second synchronous sampling sequence.

5. The method for controlling the output phase of the wide-band synchronous signal source according to claim 4, wherein the determining the reference value of the standard wide-band test signal and the determining the corresponding second time in the second synchronous sampling sequence based on the reference value and the first time comprises:
selecting a standard wide-band test signal value of the standard wide-band test signal at the start time as the reference value;
determining sampling signal values that meet a preset condition, in the second synchronous sampling sequence based on the reference value;
calculating a difference between a sampling time of each of the sampling signal values and the first time, and selecting a sampling time with a smallest difference from the first time as the second time.

6. The method for controlling the output phase of the wide-band synchronous signal source according to claim 5, wherein the calculating the phase correction control value based on the first time and the second time is performed using an expression of:
$$Δ {φ}_{n} = 360 \times {f}_{n} \times ( {T}_{n}^{c} - {T}_{n}^{s} )$$
where Δφₙ indicates an n-th phase correction control value, fₙ indicates a signal frequency of the standard wide-band test signal,
$${T}_{n}^{s}$$
indicates a first time, and
$${T}_{n}^{c}$$
indicates a second time.

7. The method for controlling the output phase of the wide-band synchronous signal source according to claim 6, wherein the obtaining the final phase correction control value based on the plurality of phase correction control values is performed using an expression of:
$$Δ φ = \frac{1}{H} ( Δ {φ}_{1} + Δ {φ}_{2} + … + Δ {φ}_{H} )$$
wherein Δφ indicates a final phase correction control value, H indicates a preset threshold, and Δφ_{H} indicates an H-th phase correction control value.

8. (canceled)

9. A computer-readable storage medium having a computer program stored thereon, the computer program, when executed by a processor, implements steps comprising:
step S101, setting a master clock signal source to output a pulse-per-second signal;
step S102, setting a parameter of the wide-band synchronous signal source to output a standard wide-band test signal;
step S103, acquiring a first synchronous sampling sequence and a second synchronous sampling sequence respectively based on the pulse-per-second signal and the standard wide-band test signal;
step S104, determining a sampling time of any rising edge signal in the first synchronous sampling sequence as a first time;
step S105, determining a reference value of the standard wide-band test signal, and determining a corresponding second time in the second synchronous sampling sequence based on the reference value and the first time;
step S106, calculating a phase correction control value based on the first time and the second time, and outputting the phase correction control value;
step S107, when a number of obtained phase correction control values is less than a preset threshold, repeating the steps S102-S106, until the number of obtained phase correction control values is greater than the preset threshold; and
step S108, when the number of obtained phase correction control values is greater than the preset threshold, obtaining a final phase correction control value based on a plurality of phase correction control values, and obtaining a corrected standard wide-band test signal based on the final phase correction control value.

10. A computer device comprising a memory and a processor, wherein the memory stores a computer program, and the processor implements, when executing the computer program, a method for controlling the output phase of the wide-band synchronous signal source comprising:
step S101, setting a master clock signal source to output a pulse-per-second signal;
step S102, setting a parameter of the wide-band synchronous signal source to output a standard wide-band test signal;
step S103, acquiring a first synchronous sampling sequence and a second synchronous sampling sequence respectively based on the pulse-per-second signal and the standard wide-band test signal;
step S104, determining a sampling time of any rising edge signal in the first synchronous sampling sequence as a first time;
step S105, determining a reference value of the standard wide-band test signal, and determining a corresponding second time in the second synchronous sampling sequence based on the reference value and the first time;
step S106, calculating a phase correction control value based on the first time and the second time, and outputting the phase correction control value;
step S107, when a number of obtained phase correction control values is less than a preset threshold, repeating the steps S102-S106, until the number of obtained phase correction control values is greater than the preset threshold; and
step S108, when the number of obtained phase correction control values is greater than the preset threshold, obtaining a final phase correction control value based on a plurality of phase correction control values, and obtaining a corrected standard wide-band test signal based on the final phase correction control value.

11. The computer-readable storage medium according to claim 9, wherein the setting the parameter of the wide-band synchronous signal source to output the standard wide-band test signal comprises:
setting a signal amplitude, a signal frequency and a signal phase of the wide-band synchronous signal source to output a standard triangle wave signal as the standard wide-band test signal;
wherein the standard wide-band test signal is expressed by:
Mₙ=f(Aₙ,fₙ,αₙ,t),
where Mₙ indicates the standard wide-band test signal, Aₙ indicates a signal amplitude with a range of Aₙ∈[0,100], fₙ indicates a signal frequency with a range of fₙ∈[0,2500], αₙ indicates a signal phase with a range of αₙ∈[0°,360°], t indicates a time, and n indicates an n-th phase correction control value.

12. The computer-readable storage medium according to claim 11, wherein the acquiring the first synchronous sampling sequence and the second synchronous sampling sequence respectively based on the pulse-per-second signal and the standard wide-band test signal comprises:
setting a start time, an end time and a sampling frequency for a sampling of the pulse-per-second signal and the standard wide-band test signal to be the same;
sampling the pulse-per-second signal and the standard wide-band test signal respectively based on the start time, the end time and the sampling frequency to acquire the first synchronous sampling sequence and the second synchronous sampling sequence.

13. The computer-readable storage medium according to claim 12, wherein the determining the reference value of the standard wide-band test signal and the determining the corresponding second time in the second synchronous sampling sequence based on the reference value and the first time comprises:
selecting a standard wide-band test signal value of the standard wide-band test signal at the start time as the reference value;
determining sampling signal values that meet a preset condition, in the second synchronous sampling sequence based on the reference value;
calculating a difference between a sampling time of each of the sampling signal values and the first time, and selecting a sampling time with a smallest difference from the first time as the second time.

14. The computer-readable storage medium according to claim 13, wherein the calculating the phase correction control value based on the first time and the second time is performed using an expression of:
$$Δ {φ}_{n} = 360 \times {f}_{n} \times ( {T}_{n}^{c} - {T}_{n}^{s} )$$
where Δφₙ indicates an n-th phase correction control value, fₙ indicates a signal frequency of the standard wide-band test signal,
$${T}_{n}^{s}$$
indicates a first time, and
$${T}_{n}^{c}$$
indicates a second time.

15. The computer-readable storage medium according to claim 14, wherein the obtaining the final phase correction control value based on the plurality of phase correction control values is performed using an expression of:
$$Δ φ = \frac{1}{H} ( Δ {φ}_{1} + Δ {φ}_{2} + … + Δ {φ}_{H} )$$
wherein Δφ indicates a final phase correction control value, H indicates a preset threshold, and Δφ_{H} indicates an H-th phase correction control value.

16. The computer device according to claim 10, wherein the pulse-per-second signal is a one pulse-per-second signal.

17. The computer device according to claim 16, wherein the setting the parameter of the wide-band synchronous signal source to output the standard wide-band test signal comprises:
setting a signal amplitude, a signal frequency and a signal phase of the wide-band synchronous signal source to output a standard triangle wave signal as the standard wide-band test signal;
wherein the standard wide-band test signal is expressed by:
Mₙ=f(Aₙ,fₙ,αₙ,t),
where Mₙ indicates the standard wide-band test signal, Aₙ indicates a signal amplitude with a range of Aₙ∈[0,100], fₙ indicates a signal frequency with a range of fₙ∈[0,2500], αₙ indicates a signal phase with a range of αₙ∈[0°,360°], t indicates a time, and n indicates an n-th phase correction control value.

18. The computer device according to claim 17, wherein the acquiring the first synchronous sampling sequence and the second synchronous sampling sequence respectively based on the pulse-per-second signal and the standard wide-band test signal comprises:
setting a start time, an end time and a sampling frequency for a sampling of the pulse-per-second signal and the standard wide-band test signal to be the same;
sampling the pulse-per-second signal and the standard wide-band test signal respectively based on the start time, the end time and the sampling frequency to acquire the first synchronous sampling sequence and the second synchronous sampling sequence.

19. The computer device according to claim 18, wherein the determining the reference value of the standard wide-band test signal and the determining the corresponding second time in the second synchronous sampling sequence based on the reference value and the first time comprises:
selecting a standard wide-band test signal value of the standard wide-band test signal at the start time as the reference value;
determining sampling signal values that meet a preset condition, in the second synchronous sampling sequence based on the reference value;
calculating a difference between a sampling time of each of the sampling signal values and the first time, and selecting a sampling time with a smallest difference from the first time as the second time.

20. The computer device according to claim 19, wherein the calculating the phase correction control value based on the first time and the second time is performed using an expression of:
$$Δ {φ}_{n} = 360 \times {f}_{n} \times ( {T}_{n}^{c} - {T}_{n}^{s} )$$
where Δφₙ indicates an n-th phase correction control value, fₙ indicates a signal frequency of the standard wide-band test signal,
$${T}_{n}^{s}$$
indicates a first time, and
$${T}_{n}^{c}$$
indicates a second time.

21. The computer device according to claim 20, wherein the obtaining the final phase correction control value based on the plurality of phase correction control values is performed using an expression of:
$$Δ φ = \frac{1}{H} ( Δ {φ}_{1} + Δ {φ}_{2} + … + Δ {φ}_{H} )$$
wherein Δφ indicates a final phase correction control value, H indicates a preset threshold, and Δφ_{H} indicates an H-th phase correction control value.
